(19) United States
(12) Patent Application Publication
(10) Pub. No.: US 2025/0096071 A1
(43) Pub. Date: Mar. 20, 2025

(54) INTEGRATED CIRCUIT COOLING SYSTEMS AND METHODS

(71) Applicant: Taiwan Semiconductor Manufacturing Company, Ltd., Hsinchu (TW)

(72) Inventors: Tsunyen Wu, Hsinchu (TW); Po-Yao Lin, Hsinchu (TW); Sing-Da Jiang, Hsinchu (TW); Shih-Wei Liu, Hsinchu (TW); Kathy Yan, Hsinchu (TW)

(73) Assignee: Taiwan Semiconductor Manufacturing Company, Ltd., Hsinchu (TW)

(21) Appl. No.: 18/467,979

(22) Filed: Sep. 15, 2023

(51) Int. Cl. H01L 23/40; H01L 23/00; H01L 23/44; H01L 25/00; H01L 25/065

(52) U.S. Cl. CPC H01L 23/4012; H01L 23/44; H01L 24/32; H01L 25/0652; H01L 25/50; H01L 2023/4062; H01L 2023/4087; H01L 24/16; H01L 24/73; H01L 2224/16145; H01L 2224/32221; H01L 2224/73253

(57) ABSTRACT

Provided are integrated circuit systems and methods for fabricating semiconductor packages. An integrated circuit system includes a circuit board having a top side and a bottom side and defining an opening from the top side to the bottom side; a bottom boiling plate having a recessed portion and having a projection with a terminal surface, wherein the recessed portion is located below the bottom side of the circuit board, wherein the projection extends through the opening, and wherein the terminal surface is located above the top side of the circuit board; a semiconductor substrate located over the top side of the circuit board and including semiconductor devices; and a top boiling plate located over the semiconductor substrate, wherein the bottom boiling plate and the top boiling plate are configured to dissipate heat away from the integrated circuit system.

### BACKGROUND

The semiconductor integrated circuit (IC) industry has experienced rapid growth. Technological advances in IC materials and design have produced generations of ICs where each generation has smaller and more complex circuits than the previous generation. The demand for smaller electronic devices has also grown recently, and therefore a need has grown for smaller and more creative packaging techniques for semiconductor dies. As the packaging density of microelectronic devices increases thanks to technological developments, manufacturers are continually shrinking the sizes of microelectronic devices to satisfy increasing demand for smaller electronic devices. Another trend in modern microelectronic devices is the increasing use of higher power consumption circuits. In order to accommodate the more densely packaged microelectronic devices with higher power consumption, the heat dissipation properties of the packaging of integrated circuits needs to be improved.

In the packaging of integrated circuits, one or more semiconductor dies may be bonded to a heat spreader (which is sometimes referred to as a heat sink) for heat dissipation. However, heat dissipation is a challenge in semiconductor packaging. A bottleneck may hamper the efficient dissipation of heat generated in the inner chips of the semiconductor package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional schematic view of an integrated circuit system provided with bi-directional cooling, in accordance with some embodiments.

FIG. 2 is a cross-sectional schematic view of the top thermally conductive member, bottom thermally conductive member, and system board of the integrated circuit system of FIG. 1.

FIG. 3 is a cross-sectional schematic view of the chip-on-wafer-on-substrate (CoWoS), voltage regulation modules (VRMs), electrical connectors, dies, and frame rings of the integrated circuit system of FIG. 1.

FIG. 4 is a cross-sectional schematic view of the integrated circuit system of FIG. 1 in a cooling tank, in accordance with some embodiments.

FIGS. 5-8 are cross-sectional schematic views, similar to FIG. 1, of the integrated circuit system during successive fabrication stages, in accordance with some embodiments.

FIG. 9 is a cross-sectional schematic view focused on the front side components of the integrated circuit system, in accordance with some embodiments.

FIG. 10 is a cross-sectional schematic view focused on the back side components of the integrated circuit system, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. As used herein, “directly over” refers to a vertical alignment of features such that when an overlying feature that is directly over an underlying feature, a vertical axis passes through both features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “directly over”, “over”, “overlying”, “above”, “upper”, “top”, “under”, “underlying”, “beneath”, “below”, “lower”, “bottom”, “side”, “positive slope” and “negative slope” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

All numbers in this description indicating amounts, ratios of materials, physical properties of materials, and/or use are to be understood as modified by the word “about,” except as otherwise explicitly indicated. When modifying a numerical value in the specification or claims, “about” denotes an interval of accuracy, familiar and acceptable to a person skilled in the art. In general, such interval of accuracy is ±ten percent. Thus, “about ten” means nine to eleven.

In certain embodiments herein, a “material layer” is a layer that includes at least 50 wt. % of the identified material, for example at least 60 wt. % of the identified material, or at least 75 wt. % of the identified material, or at least 90 wt. % of the identified material; and a layer that is a “material” includes at least 50 wt. % of the identified material, for example at least 60 wt. % of the identified material, at least 75 wt. % of the identified material, or at least 90 wt. % of the identified material. For example, certain embodiments, each of a titanium nitride layer and a layer that is titanium nitride is a layer that is at least 50 wt. %, at least 60 wt. %, at least 75 wt. %, titanium nitride, or at least 90 wt. % titanium nitride.

For the sake of brevity, well-known techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

An integrated circuit system 100 or semiconductor package 100 with improved heat-dissipating ability and the method of forming the same are provided in accordance with various embodiments. The intermediate stages of forming the semiconductor package 100 are illustrated. The variations of the embodiments are discussed. Throughout the various views and illustrative embodiments, like reference numbers are used to designate like elements.

In some embodiments, a two-phase immersion cooling thermal liquid is used to dissipate heat from heat sources on both sides of a system-on-substrate package design. For example, heat sources in the form of integrated circuit device, or chip-on-wafer (CoW), may be formed on a front side of a substrate, while voltage regulator modules (VRMs) are formed on the back side of the substrate. A top thermally conductive member, such as a top boiling plate, is dedicated to removing heat from, i.e., cool, the front side components of the substrate, i.e., the system-on-chip (SOC) dies in a multi-chip-module (MCM). A bottom thermally conductive member, such as a bottom boiling plate, is dedicated to remove heat from, i.e., cool, the back side components of the substrate i.e., the VRMs. To allow thermal coupling from the back side components to the bottom thermally conductive member, a cutout or opening is formed in the system board over which the substrate is mounted. Thus, the bottom thermally conductive member, or a portion of the bottom thermally conductive member, extends through the cutout or opening in the system board. The outer surfaces of the top and bottom thermally conductive members provide increased surface area for heat transfer to the cooling thermal liquid.

Locating the VRMs on the back side of the substrate may allow for locating the VRMs closer to the computing die than otherwise possible.

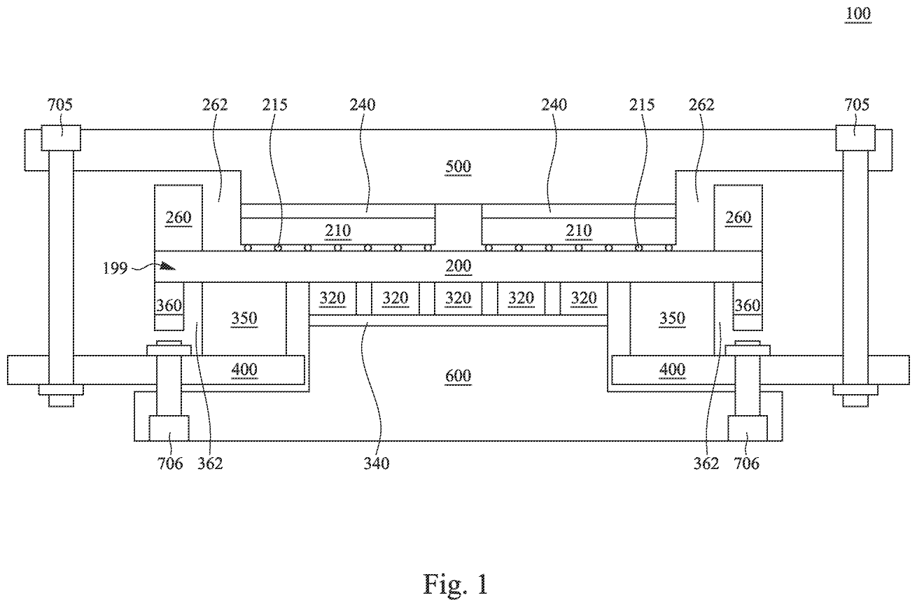

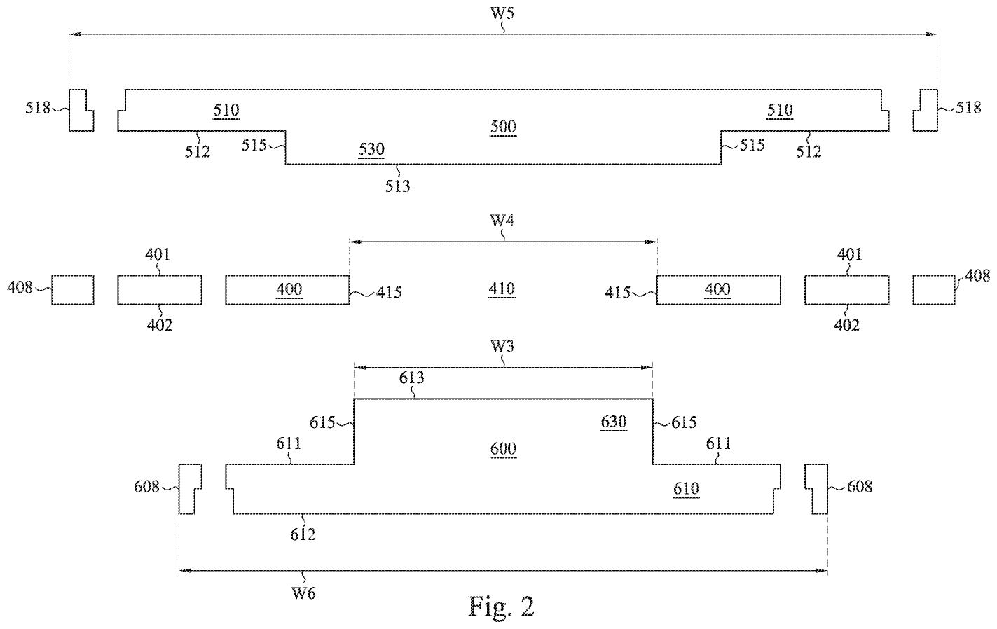

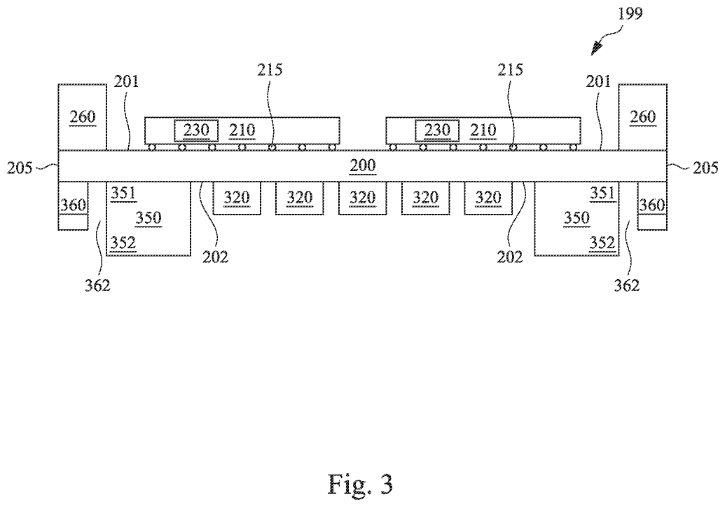

FIG. 1 is a schematic view of an integrated circuit system 100, while FIG. 2 and FIG. 3 show various components of the integrated circuit system 100 in isolation for clarity. As shown in FIGS. 1 and 3, the integrated circuit system 100 includes a chip-on-wafer-on-substrate (CoWoS) 199, i.e., a multi-chip module (MCM) substrate 199. The chip-on-wafer-on-substrate (CoWoS) 199 may be a 2.5 dimensional integrated circuit (2.5D IC) through-silicon via (TSV) interposer-based structure. For example, the chip-on-wafer-on-substrate (CoWoS) 199 may include a substrate 200 and a die or dies 210 formed over the substrate 200. The substrate 200 may include various layers, including conductive or insulating layers formed on a semiconductor substrate. The substrate 200 may include various doping configurations depending on design requirements as is known in the art. The substrate 200 may also include other semiconductors such as germanium, silicon carbide (SiC), silicon germanium (SiGe), or diamond. Alternatively, the substrate 200 may include a compound semiconductor and/or an alloy semiconductor. Further, the substrate 200 may optionally include an epi layer, may be strained for performance enhancement, may include a silicon-on-insulator (SOI) structure, and/or have other suitable enhancement features.

In FIGS. 1 and 3, each die 210 may include a single semiconductor die or a plurality of semiconductor dies. Further, each die 210 may include a single integrated circuit device 230 or a plurality of integrated circuit devices 230. In some embodiments, a die 210 may include a vertical stack of integrated circuit devices 230 or integrated circuit devices 230 arranged side-by-side laterally.

The substrate 200 has a front side 201 and an opposite back side 202. The sides 201 and 202 may be rectangular or square. The die or dies 210 may be formed on and over the front side 201 of the substrate 200. The substrate 200 may include semiconductor devices, metallization layers and vias, forming electrical interconnection paths. Each die 210 may be electrically connected to an electrical interconnection path via electrical connectors 215. The electrical connectors 215 may be solder balls, bumps, microbumps, or the like.

The substrate 200 includes a periphery 205. In certain embodiments, a top ring or frame 260 is located on or over the front side 201 and a bottom ring or frame 360 is located on or over the back side 202 of the substrate 200 at the periphery 205. As noted above, the substrate 200 may be rectangular or square. Thus, the ring or frame 260 and 360 may be rectangular or square. A top inner gap 262 is defined between opposite sides of the top ring or frame 260, and a bottom inner gap 362 is defined between opposite sides of the bottom ring or frame 360. The rings 260/360 may clamp the periphery 205 of the substrate 200 to prevent warpage and to provide stiffness.

The die or dies 210 may be located in the top inner gap 262 defined between opposite sides of the top ring or frame 260.

As shown in FIG. 1, a top thermal interface material (TIM) layer 240 may be located over the chip-on-wafer-on-substrate (CoWoS) 199. Specifically, the top TIM layer 240 may be located over each die 210. The top TIM layer 240 may be located in the top inner gap 262 defined between opposite sides of the top ring or frame 260. The top TIM layer 240 may be a composite thermal interface material (TIM) structure including a metal-containing matrix material layer and polymer particles that are coated with a metal cover, respectively, and embedded in the metal-containing matrix material layer. Other suitable TIM layers may be used.

In FIG. 1, a top thermally conductive member 500 is located over the front side 201 of the semiconductor substrate 200. Specifically, the top thermally conductive member 500 is located over the top TIM layer 240. For example, the top thermally conductive member 500 may contact each top TIM layer 240.

As shown in FIGS. 1 and 2, the top thermally conductive member 500 may be a boiling plate. The top thermally conductive member 500 may have a base portion 510 having an upper surface 511 and an opposite bottom surface 512. Base portion 510 may terminate laterally at distal ends 518. As shown, the upper surface 511 has a width W5 between opposite distal ends 518. Further, the top thermally conductive member 500 may have a downward projection or sag portion 530 that extends downward from the bottom surface 512 to a distal or bottom-most surface 513. The sag portion 530 terminates laterally at sidewalls 515.

The top thermally conductive member 500 is configured to dissipate heat away from the front side 201 of the substrate 200. Thus, the top thermally conductive member 500 is thermally connected to each top TIM layer 240. Specifically, the distal surface 513 is directly contacted to each top TIM layer 240.

The bottom surface 512 of the base portion 510 of the top thermally conductive member 500 may be located above and over the ring 260. The sag portion 530 of the top thermally conductive member 500 may extend into the top inner gap 262 defined between opposite sides of the top ring or frame 260, such that distal surface 513 is in the top inner gap 262.

As shown in FIGS. 1 and 3, voltage regulator modules (VRMs) 320 are located on or over the back side 202 of the semiconductor substrate 200, i.e., under the back side 202 in the orientation of the Figures. Each VRM 320 may be electrically connected to at least one of the integrated circuit devices 230 formed in the dies 210 through an electrical interconnection path through the substrate 200 and electrical connectors 215. In some embodiments, the VRMs 320 are located in the bottom inner gap 362 defined between opposite sides of the bottom ring or frame 360.

As shown in FIG. 1, the integrated circuit system 100 further includes a system board 400. In FIG. 2, the system board 400 is shown to include a top side 401 and a bottom side 402, and laterally terminates at external edges 408. The system board 400 may be a printed circuit board (PCB) and may be a mother board including a large number of other devices. The system board 400 may be rectangular or square and may be formed with an opening 410. For example, the system board 400 may have an internal sidewall 415 that bounds or borders the opening 410. The internal sidewall 415 extends to and interconnects the top side 401 and the bottom side 402. In some embodiments, the opening 410 is completely bounded by the internal sidewall 415, such the internal sidewall is endless. In other embodiments, the opening 410 is open, such that the internal sidewall 415 meets and terminates at an external edge 408 of the system board 400. In such embodiments, the opening 410 may be referred to as a notch in the external edge 408. As shown, the opening 410 has a width W4.

In some embodiments, the system board 400 is located below and directly under bottom top ring or frame 360.

As shown in FIG. 1, electrical connectors 350 may electrically connect the substrate 200 to the system board 400. Cross-referencing FIGS. 1-3, electrical connectors 350 may be located between the back side 202 of the substrate 200 and the top side 401 of the system board 400. The electrical connectors 350 may be electrically connected to at least one of the integrated circuit devices 230 formed in the dies 210 through an electrical interconnection path through the substrate 200 and electrical connector 215. Further, the electrical connectors 350 may be electrically connected to selected circuits or devices on the system board 400. In some embodiments, the electrical connectors 350 are physically mounted directly to the back side 202 of the substrate 200. In some embodiments, the electrical connectors 350 are physically mounted directly to the top side 401 of the system board 400.

In some embodiments, the electrical connectors 350 extend from within the bottom inner gap 362 defined between opposite sides of the bottom ring or frame 360 to outside the bottom inner gap 362. In other words, upper portions 351 of the electrical connectors 350 are within the bottom inner gap 362 and lower portions 352 of the electrical connectors 350 are below and outside of the bottom inner gap 362.

As shown in FIG. 1, a bottom thermal interface material (TIM) layer 340 may be located over the free surface of the VRMs 320, i.e., below VRMs 320 in the orientation of the Figures. Specifically, the bottom TIM layer 340 may be located over each VRM 320. In some embodiments, the bottom TIM layer 340 is located in the bottom inner gap 362 defined between opposite sides of the bottom ring or frame 360. The bottom TIM layer 340 may be a composite thermal interface material (TIM) structure including a metal-containing matrix material layer and polymer particles that are coated with a metal cover, respectively, and embedded in the metal-containing matrix material layer. Other suitable TIM layers may be used.

Further, a bottom thermally conductive member 600 is located over the back side 202 of the semiconductor substrate 200, i.e., below the semiconductor substrate 200 in the orientation of the Figures. Specifically, the bottom thermally conductive member 600 is located over the free surface of the bottom TIM layer 340, i.e., below the bottom TIM layer 340 in the orientation of the Figures.

Cross-referencing FIGS. 1 and 2, the bottom thermally conductive member 600 may be a boiling plate. The bottom thermally conductive member 600 may have a base portion 610 having an upper surface 611 and an opposite bottom surface 612. Further, the bottom thermally conductive member 600 may have an upward projection or mesa portion 630 that extends upward from the upper surface 611 to a distal or uppermost surface 613. The mesa portion 630 has sidewalls 615. The mesa portion 630 has a width W3 between opposite sidewalls 615. The base portion 610 has a width W6 between opposite edges 608.

The bottom thermally conductive member 600 is configured to dissipate heat away from the back side 202 of the substrate 200. Thus, the bottom thermally conductive member 600 is thermally connected to the bottom TIM layer 340. Specifically, the distal surface 613 is directly contacted to the bottom TIM layer 340. The increase in width from width W3 to width W6 may facilitate heat dissipation.

Cross-referencing FIGS. 1-3, the upper surface 611 of the base portion 610 of the bottom thermally conductive member 600 may be located below and under the ring 360. The mesa portion 630 of the bottom thermally conductive member 600 may extend into the bottom inner gap 362 defined between opposite sides of the bottom ring or frame 360, such that distal surface 613 is in the bottom inner gap 362.

Further, the mesa portion 630 of the bottom thermally conductive member 600 may extend into and through the opening 410 of the system board 400, as width W3 is less than width W4. Thus, the upper surface 611 may be located below and under the bottom side 402 of the system board 400 while the distal surface 613 is located above the top side 401 of the system board 400.

As shown in FIG. 1, a mechanical connector 706 may be provided to mechanically mount the bottom thermally conductive member 600 to the system board 400. For example, mechanical connectors 706 such as bolts may be used to mount opposite ends of the bottom thermally conductive member 600 to the system board 400. In some embodiments, the mechanical connectors 706 pass through the base portion 610 of the bottom thermally conductive member 600.

As shown in FIG. 1, a mechanical connector 705 may be provided to mechanically mount the top thermally conductive member 500 to the system board 400. For example, mechanical connectors 705 such as bolts may be used to mount opposite ends of the top thermally conductive member 500 to the system board 400. In some embodiments, the mechanical connectors 705 pass through the base portion 510 of the top thermally conductive member 500.

The mechanical connectors 705 and 706 are used to provide and ensure sufficient force for optimal thermal contact between thermal components in the system 100.

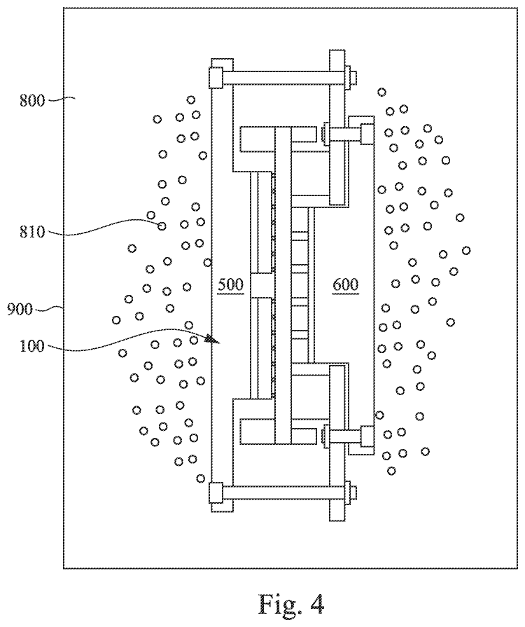

As constructed, the integrated circuit system 100 of FIG. 1 is configured to be cooled by immersion cooling, for example by two-phase immersion cooling. Specifically, as shown in FIG. 4, the integrated circuit system 100 may be located in a cooling liquid 800, such as a dielectric coolant. Heat from integrated circuit system 100 is conducted to the top and bottom thermally conductive members 500 and 600. The heat at the top and bottom thermally conductive members 500 and 600 may cause the liquid 800 to boil, thereby forming gas bubbles 810. The boiling effect carries heat away from the integrated circuit system 100. Further, the cooling liquid 800 may be engineered to have a desired boiling point, such as a boiling point lower than the boiling point of water. A low-temperature boiling point may allow the integrated circuit system 100 to operate continuously at full power without risk of failure due to overheating.

In some embodiments, the integrated circuit system 100 may be placed vertically in a tank 900 containing the cooling liquid 800, i.e., with substrate 200 extending in a vertical or near vertical direction, as shown in FIG. 4. As a result, bubbles 810 will not be trapped, such as under the bottom surface 612 of the bottom thermally conductive member 600.

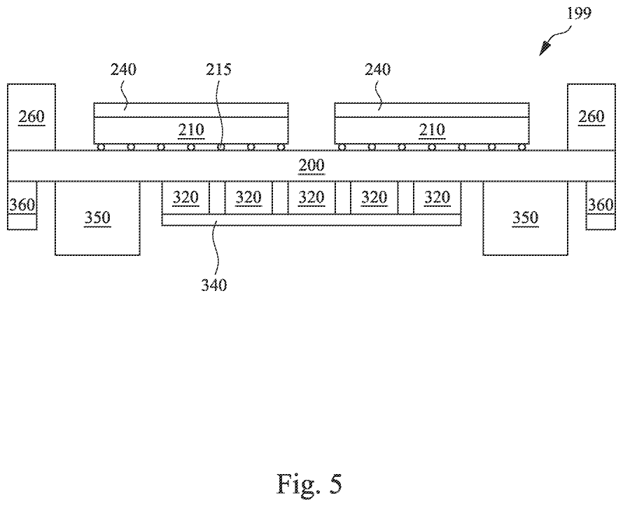

Referring to FIG. 5 illustrates an initial stage of fabrication of system 100. As shown in FIG. 5, a chip-on-wafer-on-substrate (CoWoS) 199, such as system-on-chip (SOC) dies in a multi-chip-module (MCM), is provided. Further, the chip-on-wafer-on-substrate (CoWoS) 199 includes a substrate 200, dies 210 formed over the front side 201 of the substrate 200, and connectors 215 electrically interconnected the substrate 200 and dies 210. As shown in FIG. 5, the fabrication method includes forming VRMs 320 on the back side 202 of the substrate 200. Further, the method includes forming electrical connectors 350 on the back side 202 of the substrate 200. Also, the method includes clamping the substrate 200 between top ring 260 and bottom ring 360.

As shown in FIG. 5, the method includes forming a top TIM layer 240 over the dies 210 and forming a bottom TIM layer 340 over the VRMs 320.

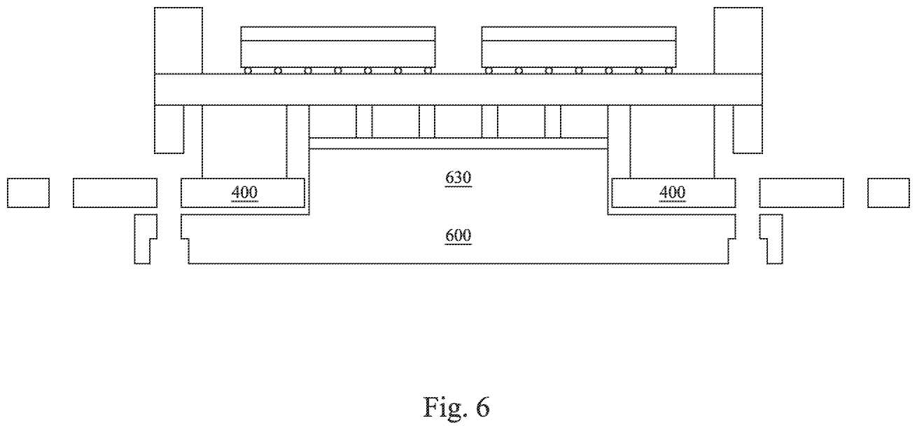

The method continues in FIG. 6 by inserting the mesa portion 630 of the bottom thermally conductive member 600 through the opening 410 in the system board 400 and into contact with the bottom TIM layer 340.

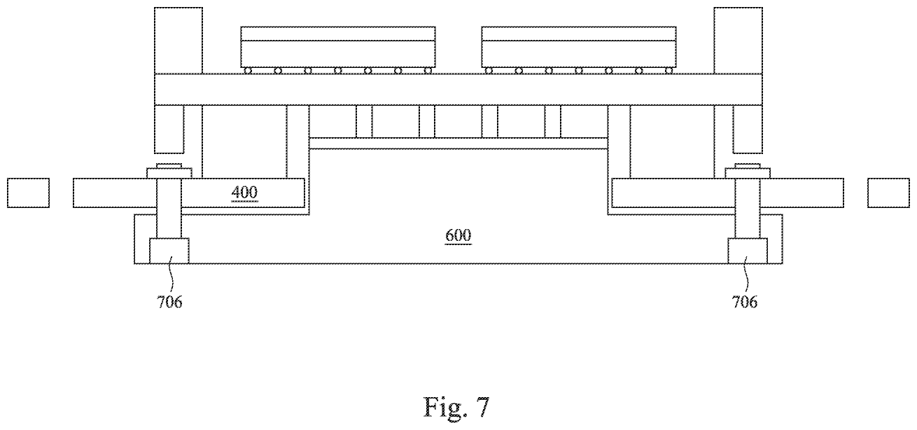

Then, at FIG. 7, the method continues with securing the bottom thermally conductive member 600 to the system board 400 with mechanical connectors 706.

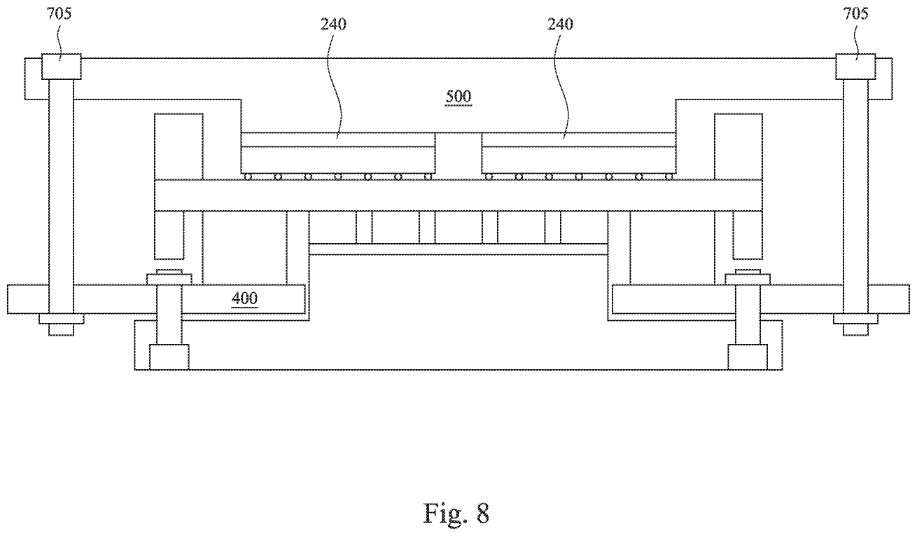

In FIG. 8, the method includes locating the top thermally conductive member 500 over the structure, and contacting the surface 513 to the top TIM layer 240. Further, the method includes securing the top thermally conductive member 500 to the system board 400 with mechanical connectors 705.

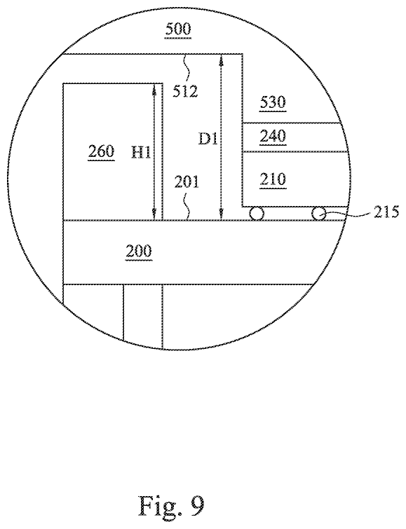

FIG. 9 provides a focused view of the top ring 260 over substrate 200. As shown, a distance D1 is defined from the bottom surface 512 of the top thermally conductive member 500 to the front side 201 of the substrate 200. Distance D1 is equal to the vertical thickness of the connectors 215, die 210, top TIM layer 240, and sag portion 530 of the top thermally conductive member 500. Further, the top ring 260 has a vertical height H1. As shown distance D1 is greater than height H1.

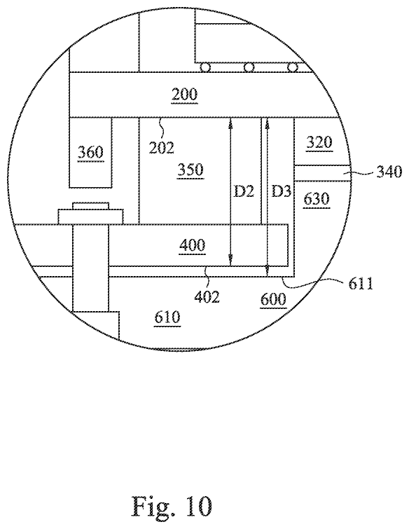

FIG. 10 provides a focused view of the electrical connector 350 under substrate 200. As shown, a distance D2 is defined from the back side 202 of the substrate 200 to the bottom side 402 of system board 400, and is equal to the vertical thickness of the electrical connector 350 and the system board 400. Further, a distance D3 is defined from the back side 202 of the substrate 200 to the upper surface 611 of the base portion 610 of the bottom thermally conductive member 600. Distance D3 is equal to the vertical thickness of VRM 320, bottom TIM layer 340, and mesa portion 630 of the bottom thermally conductive member 600. As shown, distance D3 is greater than distance D2.

As described herein, embodiments provide for increased transfer of heat away from a substrate, such as a chip-on-wafer-on-substrate (CoWoS). Specifically, heat is transferred upward, away from front side components, to a top thermally conductive member, such as top boiling plate; and heat is transferred downward, away from back side components, to a bottom thermally conductive member, such as bottom boiling plate. Such a system may be provided for use with a two-phase immersion cooling liquid.

In an embodiment, an integrated circuit system includes a circuit board having a top side and a bottom side and defining an opening from the top side to the bottom side; a bottom boiling plate having a recessed portion and having a projection with a terminal surface, wherein the recessed portion is located below the bottom side of the circuit board, wherein the projection extends through the opening, and wherein the terminal surface is located above the top side of the circuit board; a semiconductor substrate located over the top side of the circuit board and including semiconductor devices; and a top boiling plate located over the semiconductor substrate, wherein the bottom boiling plate and the top boiling plate are configured to dissipate heat away from the integrated circuit system.

In some embodiments of the integrated circuit system, the semiconductor substrate has a back side facing the terminal surface of the bottom boiling plate and a front side, wherein the semiconductor devices are formed on the front side.

In some embodiments, the integrated circuit system further includes a voltage regulator module (VRM) on the back side of the semiconductor substrate and electrically connected to at least one of the semiconductor devices.

In some embodiments, the integrated circuit system further includes a thermal interface material (TIM) contacting the terminal surface of the bottom boiling plate and the VRM.

In some embodiments, the integrated circuit system further includes a connector electrically connecting the semiconductor devices to the circuit board, wherein the connector is located between the top side of the circuit board and the back side of the semiconductor substrate.

In some embodiments of the integrated circuit, the semiconductor substrate has a back side facing the terminal surface of the bottom boiling plate and a front side, wherein the semiconductor devices are formed on dies, and wherein the dies are located on the front side of the semiconductor substrate.

In some embodiments, the integrated circuit system further includes a thermal interface material (TIM) contacting the dies and the top boiling plate.

In some embodiments, the integrated circuit system further includes a top bolt coupling the top boiling plate to the circuit board; and a bottom bolt coupling the bottom boiling plate to the circuit board.

In some embodiments, the integrated circuit system further includes a ring enclosing an outer periphery of the semiconductor substrate, wherein: the top boiling plate has base portion and a sag portion; the ring terminates at an uppermost surface located below the base portion of the top boiling plate; and the sag portion of the top boiling plate is surrounded by the ring.

In another embodiment, an integrated circuit system includes a circuit board having a top side and a bottom side and defining an opening from the top side to the bottom side; a semiconductor substrate having a front side and a back side, located over the top side of the circuit board, and including semiconductor devices on the front side; a voltage regulator module (VRM) on the back side of the semiconductor substrate and electrically connected to at least one of the semiconductor devices; and a bottom thermally conductive member extending through the opening in the circuit board and in thermal communication with the VRM to dissipate heat away from the back side of the semiconductor substrate.

In some embodiments of the integrated circuit system, the bottom thermally conductive member includes a recessed portion and has a projection with a terminal surface; the recessed portion is located below the bottom side of the circuit board; the projection extends through the opening; the terminal surface is located above the top side of the circuit board; and the terminal surface is in thermal communication with the VRM.

In some embodiments, the integrated circuit system further includes a thermal interface material interconnecting the terminal surface and the VRM.

In some embodiments, the integrated circuit system further includes a top thermally conductive member located over the front side of the semiconductor substrate, wherein the top thermally conductive member is in thermal communication with the semiconductor devices to dissipate heat away from the front side of the semiconductor substrate.

In some embodiments, the integrated circuit system further includes a thermal interface material interconnecting the top thermally conductive member and the semiconductor devices.

In another embodiment, a method for fabricating a semiconductor package includes forming an integrated circuit over a front side of a substrate; forming a voltage regulator module (VRM) on the back side of the substrate, wherein the VRM is electrically connected to the integrated circuit; thermally connecting the VRM to a bottom thermally conductive member; and thermally connecting the integrated circuit to a top thermally conductive member.

In some embodiments of the method, the bottom thermally conductive member is a bottom boiling plate; and the top thermally conductive member is a top boiling plate.

In some embodiments, the method further includes electrically connecting the integrated circuit to a circuit board, wherein the circuit board includes an opening, and wherein thermally connecting the VRM to the bottom thermally conductive member includes inserting a portion of the bottom thermally conductive member through the opening.

In some embodiments of the method, electrically connecting the integrated circuit to the circuit board includes electrically connecting the integrated circuit to the circuit board via a ring defining a gap, and wherein thermally connecting the VRM to the bottom thermally conductive member includes inserting the portion of the bottom thermally conductive member into the gap.

In some embodiments, the method further includes structurally mounting the bottom thermally conductive member to the circuit board; and structurally mounting the top thermally conductive member to the circuit board.

In some embodiments, the method further includes forming a top thermal interface material (TIM) layer over the integrated circuit, wherein thermally connecting the integrated circuit to the top thermally conductive member includes connecting the top thermally conductive member to the top TIM layer; and forming a bottom thermal interface material (TIM) layer over the VRM, wherein thermally connecting the VRM to the bottom thermally conductive member includes connecting the bottom thermally conductive member to the bottom TIM layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present.

What is claimed is:

1. An integrated circuit system comprising:
a circuit board having a top side and a bottom side and defining an opening from the top side to the bottom side;
a bottom boiling plate having a recessed portion and having a projection with a terminal surface, wherein the recessed portion is located below the bottom side of the circuit board, wherein the projection extends through the opening, and wherein the terminal surface is located above the top side of the circuit board;
a semiconductor substrate located over the top side of the circuit board and including semiconductor devices; and
a top boiling plate located over the semiconductor substrate, wherein the bottom boiling plate and the top boiling plate are configured to dissipate heat away from the integrated circuit system.

2. The integrated circuit system of claim 1, wherein the semiconductor substrate has a back side facing the terminal surface of the bottom boiling plate and a front side, wherein the semiconductor devices are formed on the front side.

3. The integrated circuit system of claim 2, further comprising a voltage regulator module (VRM) on the back side of the semiconductor substrate and electrically connected to at least one of the semiconductor devices.

4. The integrated circuit system of claim 3, further comprising a thermal interface material (TIM) contacting the terminal surface of the bottom boiling plate and the VRM.

5. The integrated circuit system of claim 2, further comprising a connector electrically connecting the semiconductor devices to the circuit board, wherein the connector is located between the top side of the circuit board and the back side of the semiconductor substrate.

6. The integrated circuit system of claim 1, wherein the semiconductor substrate has a back side facing the terminal surface of the bottom boiling plate and a front side, wherein the semiconductor devices are formed on dies, and wherein the dies are located on the front side of the semiconductor substrate.

7. The integrated circuit system of claim 6, further comprising a thermal interface material (TIM) contacting the dies and the top boiling plate.

8. The integrated circuit system of claim 1, further comprising:
a top bolt coupling the top boiling plate to the circuit board; and
a bottom bolt coupling the bottom boiling plate to the circuit board.

9. The integrated circuit system of claim 1, further comprising a ring enclosing an outer periphery of the semiconductor substrate, wherein:
the top boiling plate has base portion and a sag portion;
the ring terminates at an uppermost surface located below the base portion of the top boiling plate; and
the sag portion of the top boiling plate is surrounded by the ring.

10. An integrated circuit system comprising:
a circuit board having a top side and a bottom side and defining an opening from the top side to the bottom side;
a semiconductor substrate having a front side and a back side, located over the top side of the circuit board, and including semiconductor devices on the front side;
a voltage regulator module (VRM) on the back side of the semiconductor substrate and electrically connected to at least one of the semiconductor devices;
a bottom thermally conductive member extending through the opening in the circuit board and in thermal communication with the VRM to dissipate heat away from the back side of the semiconductor substrate.

11. The integrated circuit system of claim 10, wherein:
the bottom thermally conductive member includes a recessed portion and has a projection with a terminal surface;
the recessed portion is located below the bottom side of the circuit board;
the projection extends through the opening;
the terminal surface is located above the top side of the circuit board;
the terminal surface is in thermal communication with the VRM.

12. The integrated circuit system of claim 11, further comprising a thermal interface material interconnecting the terminal surface and the VRM.

13. The integrated circuit system of claim 10, further comprising:
a top thermally conductive member located over the front side of the semiconductor substrate, wherein the top thermally conductive member is in thermal communication with the semiconductor devices to dissipate heat away from the front side of the semiconductor substrate.

14. The integrated circuit system of claim 13, further comprising a thermal interface material interconnecting the top thermally conductive member and the semiconductor devices.

15. A method for fabricating a semiconductor package, the method comprising:
forming an integrated circuit over a front side of a substrate;
forming a voltage regulator module (VRM) on the back side of the substrate, wherein the VRM is electrically connected to the integrated circuit;
thermally connecting the VRM to a bottom thermally conductive member; and
thermally connecting the integrated circuit to a top thermally conductive member.

16. The method of claim 15, wherein:
the bottom thermally conductive member is a bottom boiling plate; and
the top thermally conductive member is a top boiling plate.

17. The method of claim 15, further comprising electrically connecting the integrated circuit to a circuit board, wherein the circuit board includes an opening, and wherein thermally connecting the VRM to the bottom thermally conductive member comprises inserting a portion of the bottom thermally conductive member through the opening.

18. The method of claim 17, wherein electrically connecting the integrated circuit to the circuit board comprises electrically connecting the integrated circuit to the circuit board via a ring defining a gap, and wherein thermally connecting the VRM to the bottom thermally conductive member comprises inserting the portion of the bottom thermally conductive member into the gap.

19. The method of claim 17, further comprising:
structurally mounting the bottom thermally conductive member to the circuit board; and
structurally mounting the top thermally conductive member to the circuit board.

20. The method of claim 15, further comprising:
forming a top thermal interface material (TIM) layer over the integrated circuit, wherein thermally connecting the integrated circuit to the top thermally conductive member comprises connecting the top thermally conductive member to the top TIM layer; and
forming a bottom thermal interface material (TIM) layer over the VRM, wherein thermally connecting the VRM to the bottom thermally conductive member comprises connecting the bottom thermally conductive member to the bottom TIM layer.
